(19) United States
(12) Patent Application Publication
(10) Pub. No.: US 2008/0264672 A1
(43) Pub. Date: Oct. 30, 2008

(54) Photoimprintable Low Dielectric Constant Material and Method for Making and Using Same

(75) Inventors: Thomas John Markley, Blandon, PA (US); Scott Jeffrey Weigel, Allentown, PA (US); Christine Peck Kretz, Macungie, PA (US)

Correspondence Address: AIR PRODUCTS AND CHEMICALS, INC.;PATENT DEPARTMENT, 7201 HAMILTON BOULEVARD, ALLENTOWN, PA, 181951501, US

(73) Assignee: AIR PRODUCTS AND CHEMICALS, INC., Allentown, PA (US)

(21) Appl. No.: 11/740,410

(22) Filed: Apr. 26, 2007

(51) Int. Cl. H05K 1/00; B29C 35/04

(52) U.S. Cl. 174/250; 264/401; 524/261

(57) ABSTRACT

A process for preparing a photoimprinted film, a composition for forming a photoimprinted film and a photoimprinted film comprising a dielectric constant of less than about 3.5. The method includes providing a material film having a composition including at least one silica source capable of being sol-gel processed, at least one photoactive compound and at least one solvent; and water. The composition contains less than about 0.1% by weight of an added acid. A mold having mold features is provided. The mold is positioned in sufficient contact with the material film to allow the material to contact at least a portion of the mold features. The material film is then exposed to a radiation source and the film is cured to form a solidified material film. The mold is separated from the solidified material, wherein the material includes film features corresponding to the mold features.

### CROSS-REFERENCE TO RELATED APPLICATIONS

This application is related to U.S. patent application Ser. No. 11/341,334 filed Jan. 27, 2006, which is hereby incorporated by reference in its entirety.

### BACKGROUND OF THE INVENTION

The present invention is directed to photoimprinting, compositions for photoimprinting and photoimprinted products and devices utilizing photoimprinted materials.

There is a continuing desire in the microelectronics industry to increase the circuit density in multilevel integrated circuit devices such as memory and logic chips in order to improve the operating speed and reduce power consumption. Current fabrication routes, such as conventional photolithography, for forming integrated circuits and similar electrical devices include numerous processing steps to place metal features in a specific location within a low dielectric constant film. These steps may include the deposition of a low dielectric film, deposition of a photoresist, creating a pattern into the photoresist, etching through the pattern into the low dielectric constant film, removal of the photoresist, and cleaning residues from the patterned film. This processing is repeated several times during the formation of an integrated circuit. These patterning steps are time consuming, expensive, and could potentially introduce defects into the device.

In order to provide a fabrication method that reduces the number of steps it is desirable to have a material that functions both as a photoresist and a low dielectric constant material. A low dielectric constant (κ) material will reduce the resistance-capacitance (“RC”) time delay of the interconnect metallization and prevent capacitive crosstalk between the different levels of metallization. Such low dielectric constant materials are desirable for premetal dielectric layers and interlevel dielectric layers. In addition, it is desirable for a material to simultaneously be photodefinable in order to permit processing capable of utilizing certain photolithographic equipment and techniques, i.e., inherently capable of forming a pattern using a lithographic process without the need for an added photoresist. Most known materials fail to possess the desired properties and provide these advantages, while providing for ease of manufacture and high-quality well-defined features, suitable for forming electronic devices.

Therefore, what is needed is a method for forming a photoimprinted low-dielectric material having reduced manufacturing time and expense.

### BRIEF SUMMARY OF THE INVENTION

One aspect of the invention includes a process for preparing a photoimprinted film comprising a dielectric constant of less than about 3.5. The method includes providing a material film having a composition including at least one silica source capable of being sol-gel processed, at least one photoactive compound and at least one solvent; and water. The composition contains less than about 0.1% by weight of an added acid. A mold having mold features is provided. The mold is positioned in sufficient contact with the material film to allow the material to contact at least a portion of the mold features. The material film is then exposed to a radiation source and the film is cured to form a solidified material film. The mold is separated from the solidified material, wherein the material includes film features corresponding to the mold features.

Another aspect of the present invention includes a photoimprintable composition capable of producing material films with a dielectric constant of less than about 3.5. The composition includes at least one partially polymerized silica source capable of being further polymerized. The composition also includes at least one photoactive compound. The composition has a degree of condensation, a solvent concentration and a viscosity sufficient to render the composition capable of forming a film that can be photoimprinted. Still another aspect of the present invention includes an electronic device having a substrate with a functional component having a material (e.g., sol-gel) film disposed on at least a portion of a surface thereof. The film has photoimprinted features, a dielectric constant of less than about 3.5. The functional component further includes circuitry for use in the electronic device.

Other features and advantages of the present invention will be apparent from the following more detailed description of the preferred embodiment, taken in conjunction with the accompanying drawings which illustrate, by way of example, the principles of the invention.

### BRIEF DESCRIPTION OF SEVERAL VIEWS OF THE DRAWINGS

FIG. 1-6 illustrates an elevational cross-sectional view of an assembly for forming photoimprinted features on a low dielectric material according to an embodiment of the present invention.

FIG. 7-12 illustrates an elevational cross-sectional view of an assembly according to an alternate embodiment for forming photoimprinted features on a low dielectric material according to an embodiment of the present invention.

### DETAILED DESCRIPTION OF THE INVENTION

The present invention includes a method for photoimprinting using a low-dielectric photodefinable silicate material. In addition, the present invention includes photoimprintable material having properties that render the composition capable of forming a film and permitting photoimprinting of the composition. Further, the present invention includes electronic devices having photoimprinted low dielectric material.

The term “photoimprintable”, “photoimprinted” and other grammatical variations thereof as used herein relate to materials that are or are capable of being subject to imprinting of features via a mold or other imprinting device wherein an in-situ curing produces a material having features corresponding to features on the imprinting device. The size of the features of the template and the resulting photoimprinted film may be of any length scale or dimension including, but not limited to, meters, millimeters, micrometers, and nanometers in length. A particularly relevant example is a length scale of nanometers in the template and resulting film, giving rise to the term “nanoimprint lithography”. Likewise, the term “photodefinable” as used herein relates to a material or film that is inherently capable of forming a pattern using a lithographic process without the need for an added photoresist. Although the material described herein is particularly suitable for providing films and the products are largely described herein as films, it is not limited thereto. The material described herein can be provided in any form capable of being deposited by spin-on deposition, among other techniques, including, without limitation, printing, slot extrusion, coatings, multi-laminar assemblies, and other types of objects that are not necessarily planar or relatively thin, and a multitude of objects not necessarily used in integrated circuits. The photoimprinted film described herein may be used, for example, in electronic devices including, without limitation, flat panel displays, batteries, flexible displays, photovoltaics, solar cells, basic logic devices, integrated circuits, memory manufacturing, RFID tags, sensors, smart objects, X-ray imaging or other imaging devices, among other devices.

In certain embodiments, the composition and/or process for preparing the composition uses chemicals within the composition and/or during processing that meet the requirements of the electronics industry because the composition contains little to no contaminants, such as, for example, metals, decomposition products of photoactive compounds, and/or other compounds that may adversely affect the electrical properties of the film. In these embodiments, the compositions described herein typically contain contaminants in amounts less than about 100 parts per million (ppm), or less than about 10 ppm, or less than about 1 ppm. In one embodiment, contaminants may be reduced by avoiding the addition of certain reagents, such as halogen-containing mineral acids or polymers synthesized using halide counter-ions or alkali metal counter-ions, into the composition because these contaminants may contribute undesirable ions to the materials described herein. In another embodiment, contaminants may be reduced by using solvents in the composition and/or during processing that contain contaminants such metals or halides in amounts less than about 10 ppm, or less than about 1 ppm, or less than about 200 parts per billion (“ppb”). In yet another embodiment, contaminants such as metals may be reduced by adding to the composition and/or using during processing chemicals containing contaminating metals in amounts less than about 10 ppm, or less than about 1 ppm, or less than about 200 ppb. In these embodiments, if the chemical contains about 10 ppm or greater of contaminating metals, the chemical may be purified prior to addition to the composition. US Patent Application Publication No. 2004-0048960, which is incorporated herein by reference in its entirety and assigned to the assignee of the present application, provides examples of suitable chemicals and methods for purifying same that can be used in the film-forming composition.

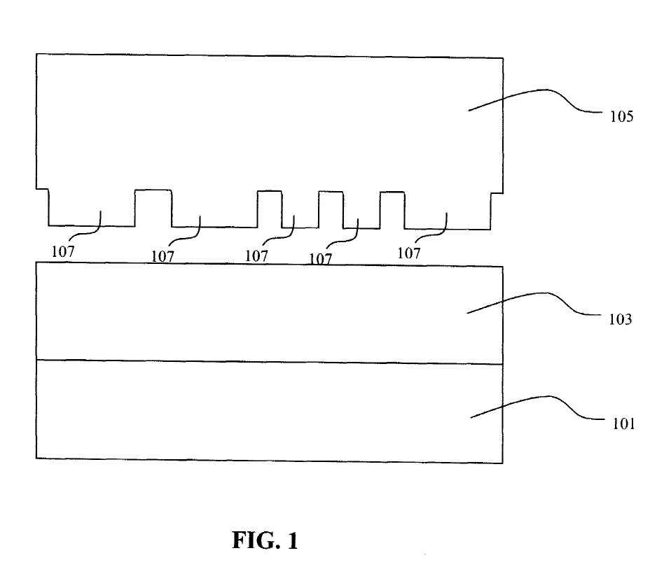

FIG. 1-6 illustrate a photoimprinting process according to an embodiment of the present invention. To produce a photoimprinted dielectric material film, first a substrate 101 is provided. The substrate 101 may be any suitable material onto which dielectric and metallized interconnects may be provided. The term “substrate”, as used herein, comprises any suitable composition that is formed before the dielectric film of the present invention is applied to and/or formed on that composition. Suitable substrates that may be used in conjunction with the present invention can comprise at least one semiconductor material such as gallium arsenide (“GaAs”), silicon, and compositions containing silicon such as at least one of crystalline silicon, polysilicon, amorphous silicon, epitaxial silicon, silicon dioxide (“SiO₂”), silica glass, silicon nitride, fused silica, glass, quartz, borosilicate glass, and combinations thereof. Other suitable substrates can comprise at least one of chromium, molybdenum, and other metals commonly employed in electronic devices, electronic displays, semiconductors, flat panel displays, and flexible display applications. Substrate 101 may also include a variety of flexible substrates such as stainless steel and a range of plastics including, but not limited to, poly(ethylene terephthalate) (PET), poly(ethylene naphthalate) (PEN), polycarbonate, and other common polymeric and plastic substrates. In addition, substrate 101 may also include layers of dielectric or other suitable materials forming a surface onto which a photoimprintable low dielectric material may be placed. As shown in FIG. 1, a material film 103 for forming a photoimprinted low dielectric material is provided on a surface of the substrate 101. The low dielectric material film 103 may be formed by any suitable technique, including, but not limited to at least one of dipping, rolling, brushing, spraying, extrusion, slot extrusion, spin-on deposition, printing, imprinting, and combinations thereof. “Film” and “material film” as used herein are not limited to the material film 103 configuration shown in FIGS. 1-5 and may include any arrangement of material on the substrate that provides material available for photoimprinting with mold 105. For example, the material film 105 may include discontinuous and/or variable thickness material application on substrate 101. Further exemplary deposition methods for forming the film 103 comprise oscillating non-contact induced spreading forces, gravity-induced spreading forces, wetting-induced spreading forces and combinations thereof. In one particular embodiment, the forming is conducted using a spin-on deposition method. Further, centrifugal force is typically used to ensure that the composition is uniformly deposited onto the substrate. In one embodiment of the present invention the composition is selectively deposited via inkjet printing of the photoimprintable material onto a substrate.

The composition making up the material film 103 according to an embodiment of the present invention is typically prepared from a composition that comprises at least one silica source capable of being sol-gel processed. Further the silica is capable of hydrolysis and/or condensation. In certain embodiments, the molar ratio of carbon to silicon atoms of all the silica sources may be about 0.5 or greater wherein the carbon is covalently bonded to the Si atom. In certain other embodiments, the composition may optionally include at least one porogen that is incapable of forming a micelle in the composition and/or optionally include at least one base to adjust the pH of the composition to a range of from about 0 to about 7. However, in certain other embodiments, the composition may optionally include at least one porogen that is capable of forming a micelle in the composition. In certain embodiments, the composition is also substantially free of an added acid. In this connection, the composition described herein does not necessarily need an added acid to catalyze the hydrolysis of chemical reagents contained therein. The composition, however, may generate an acid in situ such as, for example, in embodiments containing at least one photoactive compound comprising at least one photoacid generator that generates an acid upon exposure to an ionizing radiation source. In embodiments where an acid is added, the composition contains about 0.1% by weight or less of an added acid where the acid has a molecular weight of about 500 or less. The term “% by weight” or “wt %” as used herein refers to the percentage of the reagent relative to the total weight of the composition.

The above composition may be prepared prior to forming the material film 103. The composition according to certain embodiments of the present invention, as prepared from the composition that comprises at least one silica source capable of polymerization reactions, at least one photoactive compound, optionally at least one solvent, and water, and includes a material having a material properties (e.g., flowability, viscosity, surface tension and/or compatibility (e.g., wettability) with the mold) capable of film formation and to permit photoimprinting of the composition. In order to prepare a photoimprintable composition that is capable of forming a film and being subject to photoimprinting, the composition may be heated or otherwise subject to conditions to remove at least a portion of the solvent and water present in the composition. In one embodiment of the invention wherein the composition is ink jet printed, the prepared composition has a viscosity may be from about 0.01 to about 100 centipoise, from about 10 to about 40 centipoise or from about 10 to about 12 centipoise. In addition, the prepared material includes a thermal stability such that a partially cured or fully cured material film maintains crosslinking at temperatures up to about 400° C.

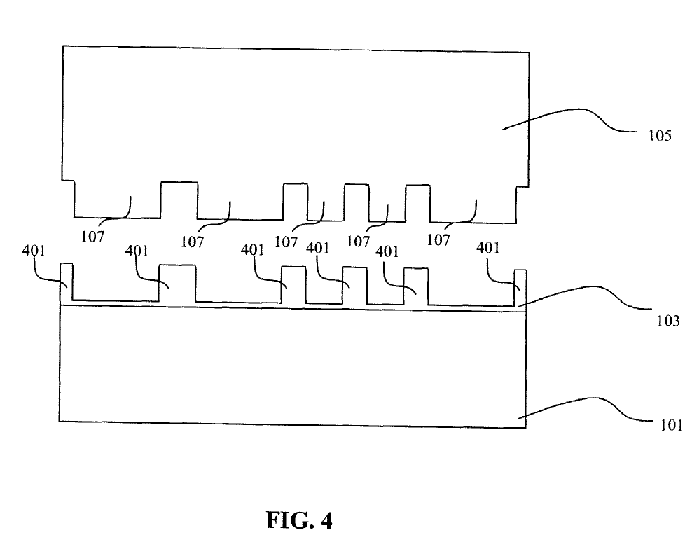

Also shown in FIG. 1, a mold 105 is provided having mold features 107. The mold features 107 correspond to the desired film features 401 (see e.g., FIG. 4) desired in the photoimprinted film 103. The mold 105 may be fabricated from a material that is transparent or otherwise permits the transmission of radiation, such as ultraviolet light or other electromagnetic energy, sufficient to cure the material in the film 103. For example, the mold 105 may be fabricated from any suitable organic or inorganic material having the ability to maintain and imprint mold features 107 under conditions of photoimprinting and photolithography. Suitable materials include silicon, silicon dioxide, silicon nitride, carbon, including carbon diamond configurations, alumina, indium, tin oxide, gallium arsenide, polymethylmethacrylates, polystyrene, polycarbonate, polytetrafluoroethylene or any other material having properties that permit transferring mold features 107 to a material film 103. Mold features 107 on mold 105 may be formed by any suitable means known in the art. The mold features 107 are not limited to the mold features 107 shown and may include any features that correspond to desired imprinted features on film 103.

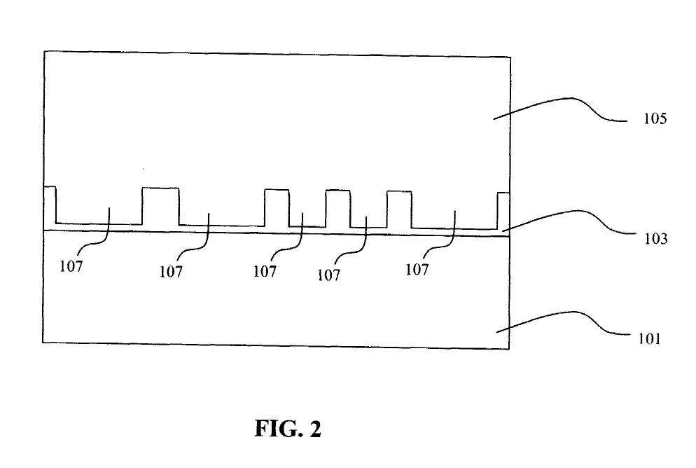

As shown in FIG. 2, in order to provide a photoimprinted low dielectric material having film features 401, a mold 105 is brought into close proximity to film 103 and substrate 101. In certain embodiments of the invention, the mold 105 is brought into contact with the substrate 101, wherein the material film 105 conforms to and is in physical contact with the mold features 107. The film 103 may be drawn into the mold features by capillary action or similar mechanisms, wherein the film features 401 to be printed conform and correspond to the mold features 107. The mold is positioned in contact with film 103 in a manner that permits the flow of material around and into mold features 107. The mold 105 may optionally be coated with a release material or other surface modifying agent know in the art for providing increased releasability and definition of the mold features 107. The positioning of mold 105 with respect to the substrate is not particularly limited and may be dependent upon the desired features, including the feature dimensions and the geometries desired.

In another embodiment of the invention, the film 103 may be provided by ink jet printing or otherwise selectively coating the surface with the photoimprintable composition. In this embodiment, the film 103 is deposited in locations or in varying thicknesses at locations at which film features 401 are desired.

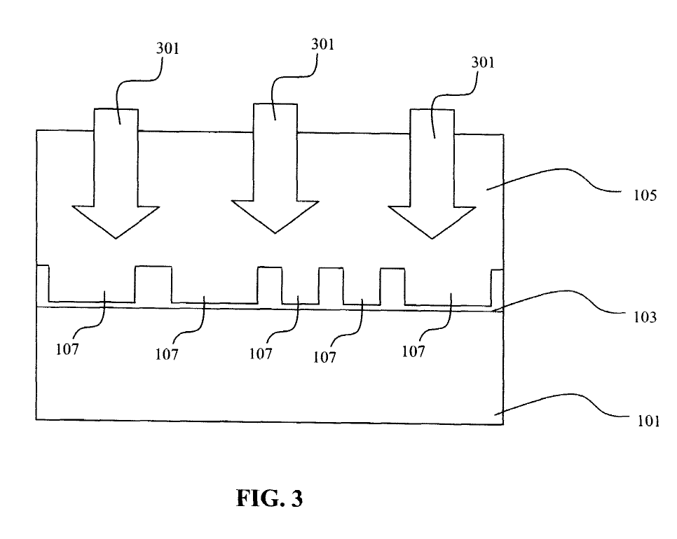

As shown in FIG. 3, radiation 301 is directed into film 103 through mold 105 to cure film 103. Although FIG. 3 shows irradiation through mold 105, radiation may be provided in any suitable manner that directs radiation 301 into film 103 sufficient to process the material of film 103 and cure the material to provide the low dielectric photoimprinted material. For example, alternative irradiation techniques may include, but is not limited to, directing radiation through the substrate or transverse to the substrate surface. Examples of sources for radiation 301 that may be used comprise ultraviolet (UV) light (e.g., ranging from deep UV to near visible light), electron beam, X-ray, laser, and/or ion beams. The ionizing radiation source may have a wavelength range of from about 1 nanometer (nm) to about 700 nm, or from about 157 nm to about 500 nm. In embodiments wherein the ionizing radiation source comprises ultraviolet light, the exposure energy may range from about 1 to about 500 mJ/cm². However, this energy level is dependent upon the exposure tool and/or the components of the coating. The radiation exposure is such that the material film 103 is provided with sufficient crosslinking of the material film to permit release of the mold 105. Additional crosslinking may be provided by exposure to radiation, thermal energy, pressure and/or any other conditions sufficient to provide a substantially fully crosslinked material.

By “cure” it is meant that the silica source present in film 103 is sol-gel processed to form a material film by any suitable mechanism in response to the exposure to radiation 301. In an embodiment of the invention, the material film is formed primarily from hydrolysis/condensation-type reactions. The material film processing (e.g., sol-gel processing) is catalyzed by acid generated within the material in film 103 and may result in crosslinking of the material film. Specifically, the composition utilized in the photoimprinting process of the present invention comprises at least one photoactive compound such as photoacid generator (PAG), photobase generator, and/or at least one photosensitizer that may act as an active ingredient within the material or film to form the low dielectric material film and provide the photoimprinted material having film features 401 (see, e.g., FIG. 4). Additionally, the photoactive compounds may additional provide additional features and/or advantages, such as the ability to act as a porogen; lower the dielectric constant; reduce swelling in the presence of solvents; prevent bridging of substrate features; and/or may be image developable in aqueous developer solutions, non-aqueous developer solutions, water, and combinations thereof.

Once the material film has formed sufficiently to maintain imprinted film features 401, the mold 105 is withdrawn from film 103, as shown in FIG. 4. The film 103 remaining on substrate 101 includes the film features 401 corresponding to the mold features 107. The film features 401 are not limited to the geometry shown, nor are the film features 401 limited to a single dimension, and may include various geometries, depths, heights and/or configurations and are dependent upon the desired features for the device.

Although not required, the film 103 having the film features 401 may be further cured via at least one energy source such as, for example, thermal, electron-beam, ozone, plasma, X-ray, ultraviolet radiation, and combinations thereof to form the patterned film. Cure conditions such as time, temperature, and atmosphere may vary depending upon the method selected, the chemical reagents within the material film forming composition, the substrate, and/or the desired pore volume. In certain embodiments, the substrate is cured using a thermal energy source such as a hot plate, oven, furnace, among other sources. In addition to single temperature curing, certain embodiments include cure steps that may be conducted at two or more temperatures. In these embodiments, the temperature for curing, which may range from about 25° C. to about 400° C., or from about 25° C. to about 300° C. In other embodiments, the coated substrate is heated to at least one temperature ranging from about 50 to about 400° C. In these embodiments, the cure step is conducted for a time of about 30 minutes or less, or about 15 minutes or less, or about 10 minutes or less. In still other embodiments, the patterned coated substrate is heated using a controlled ramp or soak. In embodiments where thermal methods are used to cure the film 103 having film features 401, curing may be conducted under controlled conditions such as atmospheric pressure using nitrogen, inert gas, air, or other N₂/O₂ mixtures (0-21% O₂), other gases, vacuum, or under reduced pressure having controlled oxygen concentration. In certain embodiments, the curing step may be conducted via a thermal method in an air, nitrogen, or inert gas atmosphere, under vacuum, or under reduced pressure having an oxygen concentration of about 10% or lower.

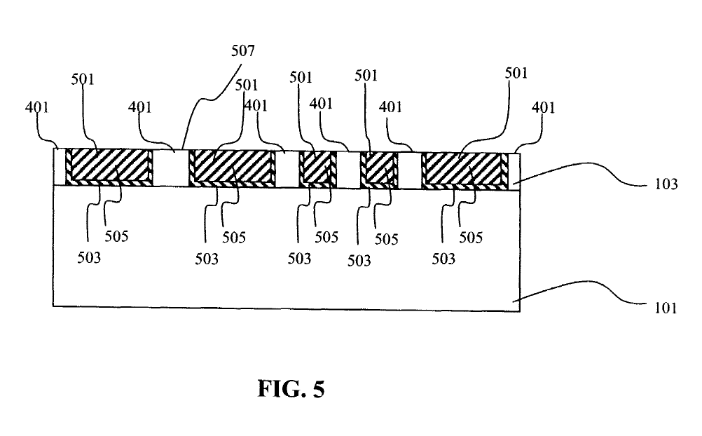

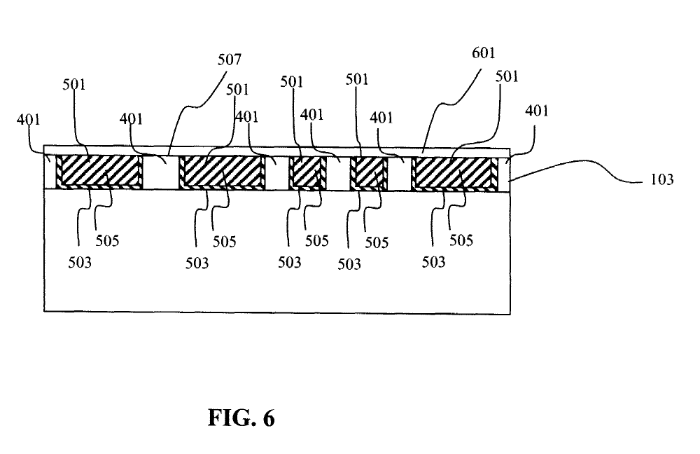

In certain embodiments, as shown in FIG. 5, it may be desirable to provide metallized or semiconductor interconnections 501 suitable for use as, for example, integrated circuits in electrical devices. The interconnections 501 may be connected or otherwise configured into circuitry to provide electrical or other functionality. Certain embodiments may further include etching through residual layers present between film features 401 to substantially expose substrate 101. Such etching may take place using any known etching technique. To form the interconnections 501, a barrier layer 503, such as a copper barrier seed layer, may be deposited on the surface of film 103. The barrier layer may be any composition known in the art to provide a suitable barrier between the dielectric film 103 and the metal layer 505. The deposition of the barrier layer 503 may include the entire surface or any portion thereof. Thereafter, a conductive material or metal layer 505 may be deposited on the barrier layer 503. The metal layer 505 and barrier layer 503 may be polished using any known polishing techniques to provide a substantially planar surface 507. The metal layer 505 may be aluminum, copper, or other conductive material. The metal layer 505 may be deposited using any known deposition techniques known in the art. Thereafter, as shown in FIG. 6, a capping layer 601 may be deposited on surface 507. Thereafter additional layers may be formed on the capping layer 601 and the process may be repeated for each additional layer. As shown in FIG. 5, the metal layer 505 includes a geometry defined by film features 401. The configuration of the interconnections 501, or circuitry, may be any configuration that provides the desired functionality to the electrical device. For example, integrated circuits may be utilized to provide microprocessing or other functionality resulting from the electrical interconnections. In one embodiment, the interconnections 501 photoimprinted on the film 103 are configured into a dual damascene structure. In another embodiment, the interconnections 501 may include voids and/or chemical compounds and/or mechanical devices that provide the interconnections with chemical or mechanical functionality. For example, the interconnections may be configured into devices, such as sensors, detectors or testing devices. Another example of devices having photoimprinted low-dielectric material is for the formation of color filters in flat panel displays. The photoimageable, photoimprintable dielectric material may be patterned so as to create wells or cavities within which color filter materials may be contained and these wells may be patterned using photoimprint technology. Photoimprinting according to the present invention may also be used for creating barrier ribs for light emitting polymers in OLED display devices.

Further, the present invention is not limited to the steps recited above and may include any additional steps suitable for providing interconnections 501. For example, ion etching, plasma etching, masking, photolithographic techniques, application of additional barrier or other coatings or any other technique known in the art for photoimprinting or photolithography may be additionally utilized to provide the desired film features 401.

As previously described, the photoimprintable composition may comprise at least one partially polymerized silica source capable of being sol-gel processed. However, the composition is not so limited. The silica sources in this embodiment are compounds capable of being sol-gel processed to form a low dielectric sol gel film. The sol gel processing may take place via any suitable chemical mechanism, such as, for example, by hydrolytic polycondensation or similar means. Monomeric or precondensed, hydrolyzable and condensable compounds having an inorganic central atom such as silicon are hydrolyzed and precondensed by adding water, and optionally a catalyst.

In certain embodiments of the invention, the material film 103 includes a low solvent, sol-gel processable silica source, wherein the low solvent composition is formed by subjecting the composition containing the silica source to solvent removal, hydrolysis and partial polymerization. In particular, by-products from hydrolysis or other reaction mechanism, such as, but not limited to, ethanol and water, may be removed by heating, distilling or other suitable solvent removal methods. The solvent removal additionally provides partial condensation of the silica source, resulting in a material having a partially polymerized silica material. The degree of condensation or amount of material permitted to condense may be sufficiently high to provide film forming capability, but sufficiently low to allow photoimprinting of the material film 103. The removal of solvent and the partial condensation is controlled to provide a resultant partially polymerized material having a combination of degree of polymerization, solvent concentration, surface tension and viscosity such that the composition may be deposited onto the substrate 101 and form material film 103. In particular, the combination of degree of condensation, solvent concentration and viscosity of the composition is such that the formed material film 103 is photoimprintable. Suitable viscosities for ink jet or similarly printable composition may include a viscosity from about 2 centipoise to about 100 centipoise, about 10 centipoise to about 40 centipoise or 10 centipoise to about 12 centipoise. The composition can then be converted into a continuous network by subsequent treatment with radiation 301 by, for example, one or more energy sources such as thermal, ultraviolet light, and/or electron beam. Additional crosslinking may optionally be provided by additional exposure to radiation and/or thermal energy. The composition for forming the low dielectric film may comprise from about 2% to about 95% by weight, or from about 10% to about 75% by weight, or from about 10% to about 65% by weight of at least one silica source.

A “silica source”, as used herein, comprises a compound comprising at least one of silicon (Si), oxygen (O), carbon (C), and optionally additional substituents such as, at least one of H, B, P, or halogen atoms, organic groups such as alkyl groups, or aryl groups. In certain embodiments of the invention, the total molar ratio of carbon to silicon atoms within the silica source contained therein is typically at least about 0.5 or greater. In determining total molar ratio of the silica source, the carbon described is that from the monovalent organic group or groups that are covalently attached to a silicon atom rather than a carbon atom present incidentally in one or more ligands such as an ethoxy ligand and/or resulting from transesterification reactions. For example, in a composition having an approximately 50/50 mixture by weight of the silica sources tetraethoxysilane (TEOS) and methyltriethoxysilane (MTES), the total molar ratio of carbon to silicon atoms of the silica sources contained therein is about 0.50. By comparison, in a composition where 100% of the silica source is MTES, the total molar ratio of carbon to silicon atoms is about 1.0.

The following are non-limiting examples of silica sources suitable for use in the composition described herein. In the chemical formulas that follow and in all chemical formulas throughout this document, the term “independently” should be understood to denote that the subject R group is not only independently selected relative to other R groups bearing different superscripts or subscripts, but is also independently selected relative to any additional species of the same R group. For example, in the formula RₐSi(OR¹)₄₋ₐ, when “a” is 2, the two R groups need not be identical to each other or to R¹. In addition, in the following formulas, the term “monovalent organic group” relates to an organic group bonded to an element of interest, such as Si or O, through a single C bond, i.e., Si—C or O—C. Examples of monovalent organic groups comprise an alkyl group, an aryl group, an unsaturated alkyl group, and/or an unsaturated alkyl group substituted with alkoxy, ester, acid, carbonyl, or alkyl carbonyl functionality. The alkyl group may be a linear, branched, or cyclic alkyl group having from 1 to 6 carbon atoms such as, for example, a methyl, ethyl, propyl, butyl, pentyl, or hexyl group. Examples of aryl groups suitable as the monovalent organic group can comprise phenyl, methylphenyl, ethylphenyl and fluorophenyl. In certain embodiments, one or more hydrogens within the alkyl group may be substituted with an additional atom such as a halogen atom (i.e., fluorine), or an oxygen atom to give a carbonyl or ether functionality.

In certain embodiments, the silica source may be represented by the following formula: RₐSi(OR¹)₄₋ₐ, wherein R independently represents a hydrogen atom, a fluorine atom, or a monovalent organic group; R¹ independently represents a monovalent organic group; and a is an integer ranging from 1 to 2. Specific examples of the compounds represented by RₐSi(OR¹)₄₋ₐ can comprise at least one member selected from the group of methyltrimethoxysilane, methyltriethoxysilane, methyltri-n-propoxysilane, methyltri-iso-propoxysilane, methyltri-n-butoxysilane, methyltri-sec-butoxysilane, methyltri-tert-butoxysilane, methyltriphenoxysilane, ethyltrimethoxysilane, ethyltriethoxysilane, ethyltri-n-propoxysilane, ethyltri-iso-propoxysilane, ethyltri-n-butoxysilane, ethyltri-sec-butoxysilane, ethyltri-tert-butoxysilane, ethyltriphenoxysilane, n-propyltrimethoxysilane, n-propyltriethoxysilane, n-propyltri-n-propoxysilane, n-propyltri-iso-propoxysilane, n-propyltin-n-butoxysilane, n-propyltri-sec-butoxysilane, n-propyltri-tert-butoxysilane, n-propyltriphenoxysilane, isopropyltrimethoxysilane, isopropyltriethoxysilane, isopropyltri-n-propoxysilane, isopropyltriisopropoxysilane, isopropyltri-n-butoxysilane, isopropyltri-sec-butoxysilane, isopropyltri-tert-butoxysilane, isopropyltriphenoxysilane, n-butyltrimethoxysilane, n-butyltriethoxysilane, n-butyltri-n-propoxysilane, n-butyltriisopropoxysilane, n-butyltri-n-butoxysilane, n-butyltri-sec-butoxysilane, n-butyltri-tert-butoxysilane, n-butyltriphenoxysilane; sec-butyltrimethoxysilane, sec-butyltriethoxysilane, sec-butyltri-n-propoxysilane, sec-butyltriisopropoxysilane, sec-butyltri-n-butoxysilane, sec-butyltri-sec-butoxysilane, sec-butyltri-tert-butoxysilane, sec-butyltriphenoxysilane, tert-butyltrimethoxysilane, tert-butyltriethoxysilane, tert-butyltri-n-propoxysilane, tert-butyltriisopropoxysilane, tert-butyltri-n-butoxysilane, tert-butyltri-sec-butoxysilane, tert-butyltri-tert-butoxysilane, tert-butyltriphenoxysilane, isobutyltrimethoxysilane, isobutyltriethoxysilane, isobutyltri-n-propoxysilane, isobutyltriisopropoxysilane, isobutyltri-n-butoxysilane, isobutyltri-sec-butoxysilane, isobutyltri-tert-butoxysilane, isobutyltriphenoxysilane, n-pentyltrimethoxysilane, n-pentyltriethoxysilane, n-pentyltri-n-propoxysilane, n-pentyltriisopropoxysilane, n-pentyltri-n-butoxysilane, n-pentyltri-sec-butoxysilane, n-pentyltri-tert-butoxysilane, n-pentyltriphenoxysilane; sec-pentyltrimethoxysilane, sec-pentyltriethoxysilane, sec-pentyltri-n-propoxysilane, sec-pentyltriisopropoxysilane, sec-pentyltri-n-butoxysilane, sec-pentyltri-sec-butoxysilane, sec-pentyltri-tert-butoxysilane, sec-pentyltriphenoxysilane, tert-pentyltrimethoxysilane, tert-pentyltriethoxysilane, tert-pentyltri-n-propoxysilane, tert-pentyltriisopropoxysilane, tert-pentyltri-n-butoxysilane, tert-pentyltri-sec-butoxysilane, tert-pentyltri-tert-butoxysilane, tert-pentyltriphenoxysilane, isopentyltrimethoxysilane, isopentyltriethoxysilane, isopentyltri-n-propoxysilane, isopentyltriisopropoxysilane, isopentyltri-n-butoxysilane, isopentyltri-sec-butoxysilane, isopentyltri-tert-butoxysilane, isopentyltriphenoxysilane, neo-pentyltrimethoxysilane, neo-pentyltriethoxysilane, neo-pentyltri-n-propoxysilane, neo-pentyltriisopropoxysilane, neo-pentyltri-n-butoxysilane, neo-pentyltri-sec-butoxysilane, neo-pentyltri-neo-butoxysilane, neo-pentyltriphenoxysilane phenyltrimethoxysilane, phenyltriethoxysilane, phenyltri-n-propoxysilane, phenyltriisopropoxysilane, phenyltri-n-butoxysilane, phenyltri-sec-butoxysilane, phenyltri-tert-butoxysilane, phenyltriphenoxysilane, δ-trifluoropropyltrimethoxysilane, δ-trifluoropropyltriethoxysilane, dimethyldimethoxysilane, dimethyldiethoxysilane, dimethyldi-n-propoxysilane, dimethyldiisopropoxysilane, dimethyldi-n-butoxysilane, dimethyldi-sec-butoxysilane, dimethyldi-tert-butoxysilane, dimethyldiphenoxysilane, diethyldimethoxysilane, diethyldiethoxysilane, diethyldi-n-propoxysilane, diethyldiisopropoxysilane, diethyldi-n-butoxysilane, diethyldi-sec-butoxysilane, diethyldi-tert-butoxysilane, diethyldiphenoxysilane, di-n-propyldimethoxysilane, di-n-propyldimethoxysilane, di-n-propyldi-n-propoxysilane, di-n-propyldiisopropoxysilane, di-n-propyldi-n-butoxysilane, di-n-propyldi-sec-butoxysilane, di-n-propyldi-tert-butoxysilane, di-n-propyldiphenoxysilane, diisopropyldimethoxysilane, diisopropyldiethoxysilane, diisopropyldi-n-propoxysilane, diisopropyldiisopropoxysilane, diisopropyldi-n-butoxysilane, diisopropyldi-sec-butoxysilane, diisopropyldi-tert-butoxysilane, diisopropyldiphenoxysilane, di-n-butyldimethoxysilane, di-n-butyldiethoxysilane, di-n-butyldi-n-propoxysilane, di-n-butyldiisopropoxysilane, di-n-butyldi-n-butoxysilane, di-n-butyldi-sec-butoxysilane, di-n-butyldi-tert-butoxysilane, di-n-butyldiphenoxysilane, di-sec-butyldimethoxysilane, di-sec-butyldiethoxysilane, di-sec-butyldi-n-propoxysilane, di-sec-butyldiisopropoxysilane, di-sec-butyldi-n-butoxysilane, di-sec-butyldi-sec-butoxysilane, di-sec-butyldi-tert-butoxysilane, di-sec-butyldiphenoxysilane, di-tert-butyldimethoxysilane, di-tert-butyldiethoxysilane, di-tert-butyldi-n-propoxysilane, di-tert-butyldiisopropoxysilane, di-tert-butyldi-n-butoxysilane, di-tert-butyldi-sec-butoxysilane, di-tert-butyldi-tert-butoxysilane, di-tert-butyldiphenoxysilane, diphenyldimethoxysilane, diphenyldiethoxysilane, diphenyldi-n-propoxysilane, diphenyldiisopropoxysilane, diphenyldi-n-butoxysilane, diphenyldi-sec-butoxysilane, diphenyldi-tert-butoxysilane, diphenyldiphenoxysilane, methylneopentyldimethoxysilane, methylneopentyldiethoxysilane, methyldimethoxysilane, ethyldimethoxysilane, n-propyldimethoxysilane, isopropyldimethoxysilane, n-butyldimethoxysilane, sec-butyldimethoxysilane, tert-butyldimethoxysilane, isobutyldimethoxysiiane, n-pentyldimethoxysilane, sec-pentyldimethoxysilane, tert-pentyldimethoxysilane, isopentyldimethoxysilane, neopentyldimethoxysilane, neohexyldimethoxysilane, cyclohexyldimethoxysilane, phenyldimethoxysilane, methyldiethoxysilane, ethyldiethoxysilane, n-propyldiethoxysilane, isopropyldiethoxysilane, n-butyldiethoxysilane, sec-butyldiethoxysilane, tert-butyldiethoxysilane, isobutyldiethoxysilane, n-pentyldiethoxysilane, sec-pentyldiethoxysilane, tert-pentyldiethoxysilane, isopentyldiethoxysilane, neopentyldiethoxysilane, neohexyldiethoxysilane, cyclohexyldiethoxysilane, phenyldiethoxysilane, trimethoxysilane, triethoxysilane, tri-n-propoxysilane, triisopropoxysilane, tri-n-butoxysilane, tri-sec-butoxysilane, tri-tert-butoxysilane, triphenoxysilane, allyltrimethoxysilane, allyltriethoxysilane, vinyltrimethoxsilane, vinyltriethoxysilane, (3-acryloxypropyl)trimethoxysilane, allyltrimethoxysilane, allyltriethoxysilane, vinyltrimethoxsilane, vinyltriethoxysilane, and (3-acryloxypropyl)trimethoxysilane. Of the above compounds, some particularly useful compounds are methyltrimethoxysilane, methyltriethoxysilane, methyltri-n-propoxysilane, methyltriisopropoxysilane, ethyltrimethoxysilane, ethyltriethoxysilane, dimethyldimethoxysilane, dimethyldiethoxysilane, diethyldimethoxysilane, and diethyldiethoxysilane.

The silica source may comprise a compound having the formula Si(OR²)₄ wherein R² independently represents a monovalent organic group. Specific examples of the compounds represented by Si(OR²)₄ comprise at least one of tetramethoxysilane, tetraethoxysilane, tetra-n-propoxysilane, tetraisopropoxysilane, tetra-n-butoxysilane, tetra-sec-butoxysilane, tetra-tert-butoxysilane, tetraacetoxysilane, and tetraphenoxysilane. Useful compounds may comprise at least one of tetramethoxysilane, tetraethoxysilane, tetra-n-propoxysilane, tetraisopropoxysilane, or tetraphenoxysilane.

The silica source may comprise a compound having the formula R³_{b}(R⁴O)_{3-b}Si—(R⁷)—Si(OR⁵)_{3-c}R⁶_{c}, wherein R³ and R⁶ are independently a hydrogen atom, a fluorine atom, or a monovalent organic group; R⁴ and R⁵ are independently a monovalent organic group; b and c may be the same or different and each is a number ranging from 0 to 2; R⁷ is an oxygen atom, a phenylene group, a biphenyl, a naphthalene group, or a group represented by —(CH₂)ₙ—, wherein n is an integer ranging from 1 to 6; or combinations thereof. Specific examples of these compounds wherein R⁷ is an oxygen atom can comprise at least one member selected from the group of hexamethoxydisiloxane, hexaethoxydisiloxane, hexaphenoxydisiloxane, 1,1,1,3,3-pentamethoxy-3-methyldisiloxane, 1,1,1,3,3-pentaethoxy-3-methyldisiloxane, 1,1,1,3,3-pentamethoxy-3-phenyldisiloxane, 1,1,1,3,3-pentaethoxy-3-phenyldisiloxane, 1,1,3,3-tetramethoxy-1,3-dimethyldisiloxane, 1,1,3,3-tetraethoxy-1,3-dimethyldisiloxane, 1,1,3,3-tetramethoxy-1,3-diphenyldisiloxane, 1,1,3,3-tetraethoxy-1,3-diphenyldisiloxane, 1,1,3-trimethoxy-1,3,3-trimethyldisiloxane, 1,1,3-triethoxy-1,3,3-trimethyldisiloxane, 1,1,3-trimethoxy-1,3,3-triphenyldisiloxane, 1,1,3-triethoxy-1,3,3-triphenyldisiloxane, 1,3-dimethoxy-1,1,3,3-tetramethyldisiloxane, 1,3-diethoxy-1,1,3,3-tetramethyldisiloxane, 1,3-dimethoxy-1,1,3,3-tetraphenyldisiloxane and 1,3-diethoxy-1,1,3,3-tetraphenyldisiloxane. Useful compounds can comprise at least one of hexamethoxydisiloxane, hexaethoxydisiloxane, hexaphenoxydisiloxane, 1,1,3,3-tetramethoxy-1,3-dimethyldisiloxane, 1,1,3,3-tetraethoxy-1,3-dimethyldisiloxane, 1,1,3,3-tetramethoxy-1,3-diphenyldisiloxane, 1,3-dimethoxy-1,1,3,3-tetramethyldisiloxane, 1,3-diethoxy-1,1,3,3-tetramethyldisiloxane, 1,3-dimethoxy-1,1,3,3-tetraphenyldisiloxane; 1,3-diethoxy-1,1,3,3-tetraphenyldisiloxane. Specific examples of these compounds wherein R⁷ is a group represented by —(CH₂)ₙ-include: bis(trimethoxysilyl)methane, bis(triethoxysilyl)methane, bis(triphenoxysilyl)methane, bis(dimethoxymethylsilyl)methane, bis(diethoxymethylsilyl)methane, bis(dimethoxyphenylsilyl)methane, bis(diethoxyphenylsilyl)methane, bis(methoxydimethylsilyl)methane, bis(ethoxydimethylsilyl)methane, bis(methoxydiphenylsilyl)methane, bis(ethoxydiphenylsilyl)methane, 1,2-bis(trimethoxysilyl)ethane, 1,2-bis(triethoxysilyl)ethane, 1,2-bis(triphenoxysilyl)ethane, 1,2-bis(dimethoxymethylsilyl)ethane, 1,2-bis(diethoxymethylsilyl)ethane, 1,2-bis(dimethoxyphenylsilyl)ethane, 1,2-bis(diethoxyphenylsilyl)ethane, 1,2-bis(methoxydimethylsilyl)ethane, 1,2-bis(ethoxydimethylsilyl)ethane, 1,2-bis(methoxydiphenylsilyl)ethane, 1,2-bis(ethoxydiphenylsilyl)ethane, 1,3-bis(trimethoxysilyl)propane, 1,3-bis(triethoxysilyl)propane, 1,3-bis(triphenoxysilyl)propane, 1,3-bis(dimethoxymethylsilyl)propane, 1,3-bis(diethoxymethylsilyl)propane, 1,3-bis(dimethoxyphenylsilyl)propane, 1,3-bis(diethoxyphenylsilyl)propane, 1,3-bis(methoxydimethylsilyl)propane, 1,3-bis(ethoxydimethylsilyl)propane, 1,3-bis(methoxydiphenylsilyl)propane, and 1,3-bis(ethoxydiphenylsilyl)propane. Useful compounds can comprise bis(trimethoxysilyl)methane, bis(triethoxysilyl)methane, bis(dimethoxymethylsilyl)methane, bis(diethoxymethylsilyl)methane, bis(dimethoxyphenylsilyl)methane, bis(diethoxyphenylsilyl)methane, bis(methoxydimethylsilyl)methane, bis(ethoxydimethylsilyl)methane, bis(methoxydiphenylsilyl)methane and bis(ethoxydiphenylsilyl)methane.

In certain embodiments of the present invention, R¹ of the formula RₐSi(OR¹)₄₋ₐ; R² of the formula Si(OR²)₄; and R⁴ and/or R⁵ of the formula R³_{b}(R⁴O)_{3-b}Si—(R⁷)—Si(OR⁵)_{3-c}R⁶_{c} can each independently be a monovalent organic group of the formula:

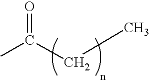

wherein n is an integer ranging from 0 to 4. Specific examples of these compounds can comprise at least one of tetraacetoxysilane, methyltriacetoxysilane, ethyltriacetoxysilane, n-propyltriacetoxysilane, isopropyltriacetoxysilane, n-butyltriacetoxysilane, sec-butyltriacetoxysilane, tert-butyltriacetoxysilane, isobutyltriacetoxysilane, n-pentyltriacetoxysilane, sec-pentyltriacetoxysilane, tert-pentyltriacetoxysilane, isopentyltriacetoxysilane, neopentyltriacetoxysilane, phenyltriacetoxysilane, dimethyldiacetoxysilane, diethyldiacetoxysilane, di-n-propyldiacetoxysilane, diisopropyldiacetoxysilane, di-n-butyldiacetoxysilane, di-sec-butyldiacetoxysilane, di-tert-butyldiacetoxysilane, diphenyldiacetoxysilane, triacetoxysilane. Useful compounds can comprise tetraacetoxysilane and methyltriacetoxysilane.

Other examples of the silica source may comprise at least one fluorinated silane or fluorinated siloxane such as those provided in U.S. Pat. No. 6,258,407; hereby incorporated by reference in its entirety. Another example of the silica source may comprise compounds that produce a Si—H bond upon elimination.

In certain embodiments, the silica source comprises at least one carboxylic acid ester bonded to the Si atom. Examples of these silica sources comprise at least one of tetraacetoxysilane, methyltriacetoxysilane, ethyltriacetoxysilane, and phenyltriacetoxysilane. In addition to the at least one silica source wherein the silica source has at least one Si atom having a carboxylate group attached thereto, the composition may further comprise additional silica sources that may not necessarily have the carboxylate attached to the Si atom.

In some embodiments, a combination of hydrophilic and hydrophobic silica sources is used in the composition. The term “hydrophilic”, as used herein, refers to compounds wherein the silicon atom can crosslink through four bonds. In these embodiments, the ratio of hydrophobic silica source to the total amount of silica source can comprise at least about 0.5 molar ratio, or ranges from about 0.5 to about 100 molar ratio, or ranges from about 0.5 to about 25 molar ratio. Some examples of hydrophilic sources comprise alkoxysilanes having an alkoxy functionality and can at least partially crosslink, e.g., a Si atom with four methoxy, ethoxy, propoxy, acetoxy, etc. groups, or materials with carbon or oxygen bonds between Si atoms and all other functionality on the Si atoms being an alkoxide. If the Si atoms do not fully crosslink, residual Si—OH groups may be present as terminal groups that can adsorb water. The term “hydrophobic” refers to compounds where at least one of the alkoxy functionalities has been replaced with a Si—C or Si—F bond, e.g., Si-methyl, Si-ethyl, Si-phenyl, Si-cyclohexyl, among other compounds that would not generate an Si—OH after hydrolysis. In these sources, the silicon would crosslink with less than four bridges even when fully crosslinked as a result of hydrolysis and condensation of Si—OH groups if the terminal group remains intact. In certain embodiments, the hydrophobic silica source comprises a methyl group attached to the silicon atom.

The material film-forming composition disclosed herein may comprise at least one added solvent. The term “added solvent” as used herein refers to any non-aqueous liquid or supercritical fluid that provides at least one of the following: solubility with the reagents, adjusts the film thickness, provides sufficient optical clarity for subsequent processing steps such as, for example, lithography, and/or may be substantially removed upon curing. The amount of added solvent that may be added to the composition is less than about 95 wt %, or from about 0% to about 50 wt %, or from about 0% to about 25 wt % by weight. Exemplary added solvents useful for the film-forming composition can comprise at least one of alcohols, ketones, amides, alcohol ethers, glycols, glycol ethers, nitriles, furans, ethers, glycol esters, and/or ester solvents. The solvents could also have hydroxyl, carbonyl, or ester functionality. In certain embodiments, the solvent has one or more hydroxyl or ester functionalities such as those solvents having the following formulas: HO—CHR⁸—CHR⁹—CH₂—CHR¹⁰R¹¹ where R⁸, R⁹, R¹⁰, and R¹¹ can be a CH₃ or H; and R¹²—CO—R¹³ where R¹² is a hydrocarbon having from 3 to 6 carbon atoms; R¹³ is a hydrocarbon having from 1 to 3 carbon atoms. Additional exemplary solvents comprise alcohol isomers having from 4 to 6 carbon atoms, ketone isomers having from 4 to 8 carbon atoms, linear or branched hydrocarbon acetates where the hydrocarbon has from 4 to 6 carbon atoms, ethylene or propylene glycol ethers, ethylene or propylene glycol ether acetates. Other solvents that can be used comprise at least one of 1-propanol, 1-hexanol, 1-butanol, ethyl acetate, butyl acetate, 1-pentanol, 2-pentanol, 2-methyl-1-butanol, 2-methyl-1-pentanol, 2-ethoxyethanol, 2-methoxyethanol, 2-propoxyethanol, 1-propoxy-2-propanol, 2-heptanone, 4-heptanone, 1-tert-butoxy-2-ethoxyethane, 2-methoxyethylacetate, propylene glycol methyl ether acetate, pentyl acetate, 1-tert-butoxy-2-propanol, 2,3-dimethyl-3-pentanol, 1-methoxy-2-butanol, 4-methyl-2-pentanol, 1-tert-butoxy-2-methoxyethane, 3-methyl-1-butanol, 2-methyl-1-butanol, 2-methoxyethanol, 3-methyl-2-pentanol, 1,2-diethoxyethane, 1-methoxy-2 propanol, 1-butanol, 3-methyl-2-butanol, 5-methyl-2-hexanol, propylene glycol propyl ether, propylene glycol methyl ether, and γ-butyrolactone. Still further exemplary added solvents comprise lactates, pyruvates, and diols.

The added solvents enumerated above may be used alone or in combination of two or more solvents. In certain embodiments wherein the film is formed by spin-on deposition, the film thickness of the coated substrate can be increased by lowering the amount of solvent present in the composition thereby increasing the solids content of the composition or, alternatively, by changing the conditions used to spin, level, and/or dry the film.

The material film forming composition disclosed herein typically comprises water. In these embodiments, the amount of water added to the composition is sufficient to perform partial and/or complete hydrolysis of the composition. The composition, however, may generate a solvent and water in situ (e.g., through hydrolysis of the reagents, decomposition of reagents, reactions within the mixture, among other interactions). Suitable ranges of added water include concentrations from about 0.1% to about 30% by weight, or from about 0.1% to about 25% by weight. Examples of water that can be added comprise deionized water, ultra pure water, distilled water, doubly distilled water, and high performance liquid chemical (HPLC) grade water or deionized water having a low metal content. In one embodiment of the invention, the generated solvent is removed by heating or otherwise volatizing the solvent.

At least one photoactive compound useable in the film-forming composition described herein. The term “photoactive compound”, as used herein, describes at least one compound that interacts, absorbs, and/or is affected by exposure to an ionizing radiation source. In certain embodiments, the amount of photoactive compound in the composition may also influence the porosity and the dielectric constant of the film. The amount of photoactive compound added to the composition may range from about 0.0001% to about 35% by weight, or from about 1% to about 20% by weight, or from about 1% to about 10% by weight. The photoactive compounds useful in the present invention can comprise at least one of photoacid generators (“PAG”), photobase generators (“PBG”), and/or photosensitizers.

In certain embodiments, the photoactive compound comprises at least one PAG. The term “photoacid generator”, as used herein, describes a compound that liberates an acid upon exposure to an ionizing radiation source. In one embodiment, the ionizing radiation source comprises a photon source such as ultraviolet light at a wavelength of about 436 nanometers (nm) or less. Suitable PAGs can comprise at least one of halogenated triazines, onium salts, sulfonated esters, diaryliodonium salts, triazines, iodonium salts, sulfonium salts, diazomethanes, and/or halogenated sulfonyloxy dicarboximides. One particular example of a PAG comprises an onium salt having weakly nucleophilic anions. Examples of such anions can comprise at least one halogen complex anion of divalent to heptavalent metals or non-metals, for example, at least one of antimony, tin, iron, bismuth, aluminum, gallium, indium, titanium, zirconium, scandium, chromium, hafnium, copper, boron, phosphorus and arsenic. Examples of suitable onium salts can comprise at least one of diaryl-diazonium salts and onium salts of group VA and B, IIA and B and I of the Periodic Table, for example, at least one of halonium salts, quaternary ammonium, phosphonium and arsonium salts, aromatic sulfonium salts and sulfoxonium salts or selenium salts. Examples of suitable onium salts are disclosed in U.S. Pat. Nos. 4,442,197; 4,603,101; and 4,624,912, all incorporated herein by reference in their entirety. Particular examples of an onium salt comprise at least one of triphenylsulfonium perfluorobutane sulfonate or nanoflate [Ph₃S]⁺[C₄F₉SO₃]⁻, bis(4-tert-butylphenyl)iodonium trifluoromethane sulfonate or triflate, or diphenyliodonium-9,10-dimethoxyanthracene-2-sulfonate. In other embodiments, the PAG comprises an sulfonated ester. The sulfonated esters useful as photoacid generators in the film-forming composition comprise sulfonyloxy ketones. Suitable sulfonated esters comprise at least one of benzoin tosylate, t-butylphenyl alpha-(p-toluenesulfonyloxy)-acetate, and t-butyl alpha-(p-toluenesulfonyloxy)acetate. Such sulfonated esters are disclosed in the Journal of Photopolymer Science and Technology, vol. 4, No. 3,337-340 (1991), incorporated herein by reference. In other embodiments, the PAG comprises a nonionic compound. Examples of suitable nonionic PAGs comprise at least one of N-hydroxyphthalimide triflate, 2-(4-Methoxystyryl)-4,6-bis(trichloromethyl)-1,3,5-triazine, and N-hydroxy-5-norbornene-2,3-dicarboximide nanoflate.

In other embodiments, the photoactive compound comprises at least one photobase generator. The term “photobase generator”, as used herein, describes a compound that liberates a base upon exposure to an ionizing radiation source. Some examples of suitable PBGs comprise at least one of 2-nitrobenzyl cyclohexanecarbamate and triphenylsulfonium hydroxide.

In still further embodiments, the photoactive compound may comprise at least one photosensitizer. The photosensitizer can be used in combination with a PAG and/or PBG. The term “photosensitizer” as used herein describes a compound that absorbs energy from the ionizing radiation source at a certain criteria such as wavelength to allow a photoacid generator or a photobase generator to release its acid or its base, respectively. In one embodiment, the photosensitizer is used in combination with a PAG to enable the PAG to generate acid upon exposure to an ionizing radiation source such as ultraviolet light at wavelengths that it normally would not release an acid. For example, if a particular PAG does not absorb light at a wavelength range of about 300 nm or greater, the addition of one or more photosensitizers may allow the composition to generate acid upon UV exposure to this wavelength range. Examples of photosensitizers that are suitable for use herein are disclosed in U.S. Pat. Nos. 4,442,197, 4,250,053, 4,371,605, and 4,491,628; which are incorporated herein by reference in their entirety. Particular examples of photosensitizers that may be used can comprise at least one of isopropyl-9H-thioxanthen-9-one (ITX), anthracene carbonitrile, anthracene methanol, the disodium salt of anthraquinone disulfonic acid, pyrene, and perylene.

The term “porogen”, as used herein, comprises at least one chemical reagent that is used to generate void volume within the resultant film. Suitable porogens for use in the dielectric materials of the present invention can comprise at least one of labile organic groups, high boiling point solvents, decomposable polymers, dendrimeric polymers, hyper-branched polymers, polyoxyalkylene compounds, small molecules, and combinations thereof.

In certain embodiments of the present invention, the porogen may comprise at least one labile organic groups. When some labile organic groups are present in the reaction composition, the labile organic groups may contain sufficient oxygen to convert to gaseous products during the cure step. Some examples of compounds containing labile organic groups comprise the compounds disclosed in U.S. Pat. No. 6,171,945, which is incorporated herein by reference in its entirety. In some embodiments of the present invention, the porogen may comprise at least one relatively high boiling point solvent. In this connection, the solvent is generally present during at least a portion of the sol-gel processing of the material film composition. Solvents typically used to aid in pore formation have relatively higher boiling points (e.g., about 170° C. or greater or about 200° C. or greater). Solvents suitable for use as a porogen within the composition of the present invention can comprise those solvents disclosed, for example, in U.S. Pat. No. 6,231,989, which is incorporated herein by reference in its entirety.

In certain embodiments, the porogen may comprise a small molecule such as those described in the reference Zheng, et al., “Synthesis of Mesoporous Silica Materials with Hydroxyacetic Acid Derivatives as Templates via a Sol-Gel Process”, J. Inorg. Organomet. Polymers, 10, 103-113 (2000) which is incorporated herein by reference, or quarternary ammonium salts such as tetrabutylammonium nitrate.

The porogen could also comprise at least one decomposable polymer. The decomposable polymer may be radiation decomposable, or typically, thermally decomposable. The term “polymer”, as used herein, also encompasses the terms oligomers and/or copolymers unless expressly stated to the contrary. Radiation decomposable polymers are polymers that decompose upon exposure to an ionizing radiation source, e.g., ultraviolet, X-ray, electron beam, among other sources. Thermally decomposable polymers undergo thermal decomposition at temperatures that approach the condensation temperature of the silica source materials and can be present during at least a portion of the cross-linking. Such polymers comprise those that may foster templating of the vitrification reaction, may control and define pore size, and/or may decompose and diffuse out of the matrix at the appropriate time in processing. Examples of these polymers comprise polymers that have an architecture that provides a three-dimensional structure such as those comprising block copolymers, e.g., diblock, triblock, and multiblock copolymers; star block copolymers; radial diblock copolymers; graft diblock copolymers; cografted copolymers; random copolymers, dendrigraft copolymers; tapered block copolymers; and combinations of these architectures. Further examples of decomposable polymers comprise the degradable polymers disclosed in U.S. Pat. No. 6,204,202, which is incorporated herein by reference in its entirety. Some particular examples of decomposable polymers comprise at least one of acrylates (e.g., polymethylmethacrylate methylacrylic acid co-polymers (PMMA-MAA) and poly(alkylene carbonates), polyurethanes, polyethylene, polystyrene, other unsaturated carbon-based polymers and copolymers, poly(oxyalkylene), epoxy resins, and siloxane copolymers).

The porogen may comprise at least one hyper-branched or dendrimeric polymer. Hyper-branched and dendrimeric polymers generally have relatively low solution and melt viscosities, high chemical reactivity due to surface functionality, and enhanced solubility even at higher molecular weights. Some non-limiting examples of suitable decomposable hyper-branched polymers and dendrimeric polymers are disclosed in “Comprehensive Polymer Science”, 2nd Supplement, Aggarwal, pp. 71-132 (1996) that is incorporated herein by reference in its entirety.

The porogen within the film-forming composition may also comprise at least one polyoxyalkylene compound such as polyoxyalkylene non-ionic surfactants provided that the polyoxyalkylene non-ionic surfactants are incapable of forming a micelle in the composition, polyoxyalkylene polymers, polyoxyalkylene copolymers, polyoxyalkylene oligomers, or combinations thereof. An example of such comprises a polyalkylene oxide that includes an alkylene moiety ranging from C₂ to C₆ such as polyethylene oxide, polypropylene oxide, and copolymers thereof.

In certain embodiments, the material film may optionally comprise at least one base. In these embodiments, the base is added in an amount sufficient to adjust the pH of the composition to a range of from about 0 to about 7. Exemplary bases can comprise at least one of quaternary ammonium salts and hydroxides, such as ammonium or tetramethylammonium hydroxide, amines such as primary, secondary, and tertiary amines, and amine oxides.

In one aspect, the photoimprinted material described herein requires no additional post-treatment steps to remove the hydroxyl functionality thereby forming a hydrophobic film. In contrast to the materials and films described herein, conventional silica-based films that contain no organic species attached to the Si atom absorb moisture from the air because the surface is terminated only in hydroxyls. Termination of the silica network with hydroxyls and water in the pore systems may result in films that exhibit a relatively higher dielectric constant. The inventive material and films can be substantially free of hydroxyl functionality.

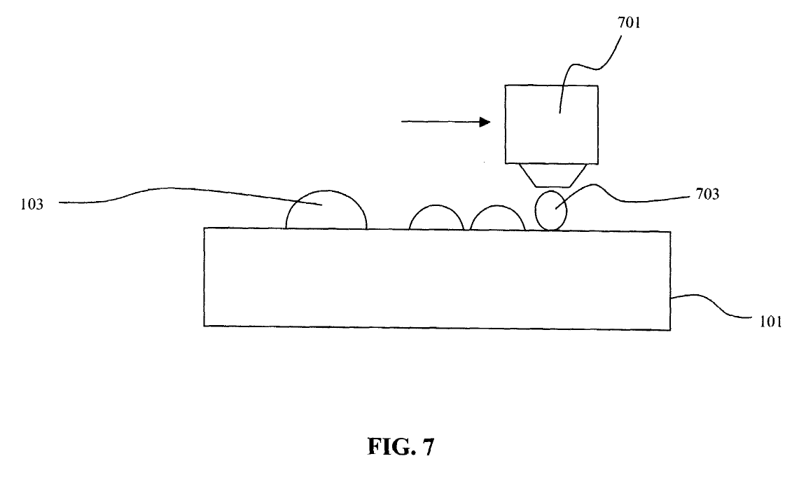

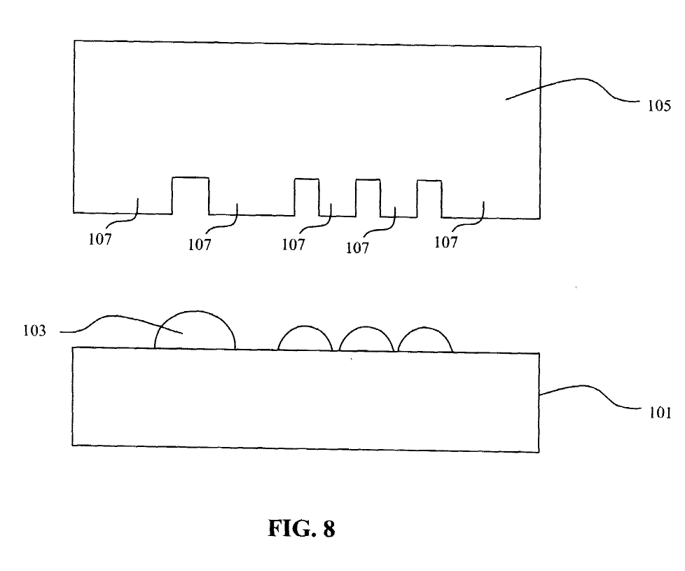

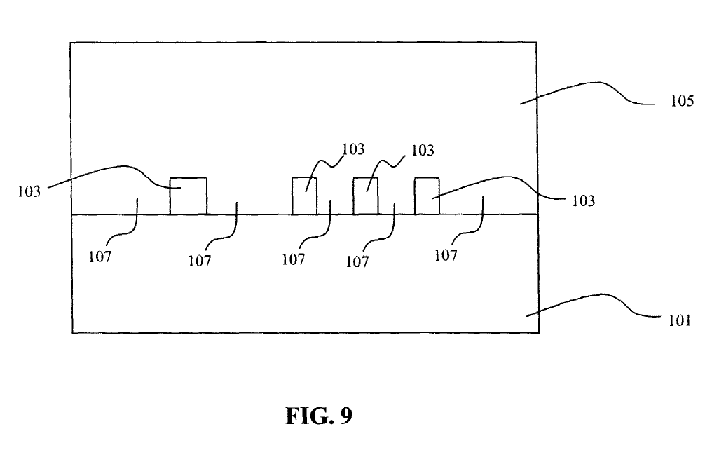

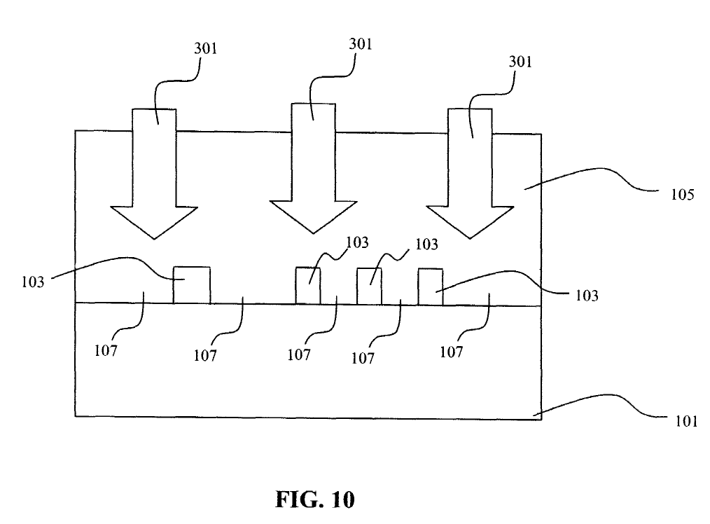

FIG. 7-12 illustrate a photoimprinting process according to another embodiment of the present invention. To produce a photoimprinted dielectric material film, a substrate 101 is provided and, as shown in FIG. 7, a printing device 701, such as an ink jet printer, is directed over the substrate 101 and printing material 703 having a composition according to an embodiment of the present invention is directed toward substrate 101. The printing material 703 forms material film 103. The printing material 703 and material film 103 may include a composition having a partially polymerized silica source and a photoactive compound. The material film 103 on substrate 101 is a discontinuous film formed from the printed pattern from printing device 701. The use of printing device 701 permits the metering of desired amounts of the photoimprintable composition on the surface corresponding to the features to be photoimprinted. This embodiment of the invention allows for efficient utilization of material with little or no waste and high quality photoimprinted films. As shown in FIG. 8, a mold 105 is provided having mold features 107 corresponding to desired film features 401 (see, e.g., FIG. 10). The mold is directed into material film 103, as shown in FIG. 9, wherein the composition of the material film conforms the features of mold 105. The material film 103 may be drawn into the mold features by capillary action or similar mechanisms, wherein the film features 401 to be printed conform and correspond to the mold features 107.

As shown in FIG. 10, radiation 301 is directed into film 103 through mold 105 to cure film 103. Although FIG. 10 shows irradiation through mold 105, radiation may be provided in any suitable manner that directs radiation 301 into film 103 sufficient to process the sol-gel film and cure the material to form the low dielectric photoimprinted material. The radiation exposure is such that the material film 103 and permits release of the mold 105. Additional crosslinking may be provided by exposure to radiation, thermal energy, pressure and/or any other conditions sufficient to provide a substantially fully cured photoimprinted material.

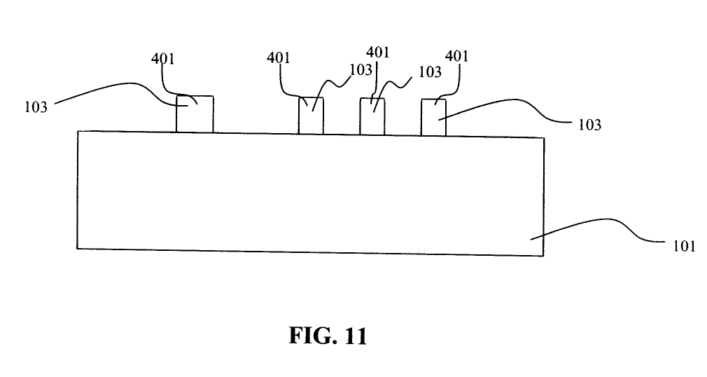

Once the film has formed sufficiently to maintain imprinted film features 401, the mold 105 is withdrawn from film 103, as shown in FIG. 11. The film 103 remaining on substrate 101 includes the film features 401 corresponding to the mold features 107. The film features 401 limited to a single dimension, and may include various geometries, depths, heights and/or configurations and are dependent upon the desired features for the device. In addition, residual material present between film features 401 may be removed by etching or other suitable removal method known in the art.

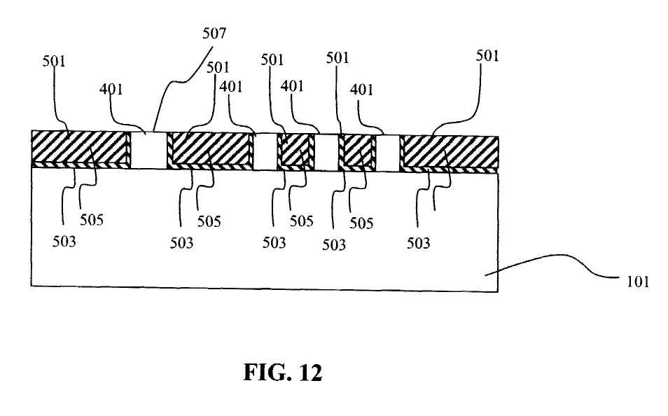

In certain embodiments, as shown in FIG. 12, it may be desirable to provide metallized or semiconductor interconnections 501 suitable for use as, for example, integrated circuits in electrical devices. These interconnections may be provided utilizing any suitable method know in the art for providing metallized or semiconductor interconnections 501. The present invention is not limited to metallized or semiconductor interconnections 501 and may include any structure or absence thereof that provides functionality to electronic devices.

In certain embodiments, the photoimprinted materials and films described herein comprise pores. In these embodiments, the photoimprinted materials and films may be mesoporous, microporous, or combinations thereof. The term “mesoporous”, as used herein, describes pore sizes that range from about 10 Å to about 500 Å, or from about 10 Å to about 100 Å, or from about 10 Å to about 50 Å. The term “microporous” describes pore sizes that range from about 10 Å or less. In certain embodiments, the photoimprinted film has a minimal number of pores. In alternative embodiments, the photoimprinted film has pores of a narrow size range and the pores are homogeneously distributed throughout the film. Films may have a porosity ranging from about 1% to about 90%. The porosity of the films may be closed or open pore. In certain embodiments, the pore system may be sealed by atomic layer deposition or other pore sealing techniques.

In certain embodiments, the diffraction pattern of the photoimprinted material or film does not exhibit diffraction peaks at a d-spacing greater than about 10 Angstroms. The diffraction pattern of the material or film may be obtained in a variety of ways such as, but not limited to, neutron, X-ray, small angle, grazing incidence, and reflectivity analytical techniques. For example, conventional x-ray diffraction data may be collected on a sample film using a conventional diffractometer such as a Siemens D5000 θ-θ diffractometer using CuKα radiation. Sample films may also be analyzed by X-ray reflectivity (XRR) data using, for example, a Rigaku ATX-G high-resolution diffraction system with Cu radiation from a rotating anode X-ray tube. Sample films may also be analyzed via small-angle neutron scattering (SANS) using, for example, a system such as the 30 meter NG7 SANS instrument at the NIST Center for Neutron Research. In alternative embodiments, the photodefinable material or film does exhibit diffraction peaks at a d-spacing greater than about 10 Angstroms.

Photoimprinted films described herein generally have a thickness that ranges from about 0.05 μm to about 5 μm, and depend upon film features 401, thereon, although lower thicknesses may be achieved. The photoimprinted films described herein may exhibit a refractive index determined at about 633 nm of between about 1.1 and about 1.5. The dielectric constant is normally less than about 3.5, or less than about 3.0 or less than about 2.0. The films described herein are thermally stable at temperatures of about 250° C. or greater.

In certain embodiments, the photoimprinted film exhibits a transmittance of about 50% or greater at a wavelength of about 193 nm or greater, or about 75% or greater at a wavelength of about 248 nm or greater, or greater than about 90% at a wavelength of about 365 nm or greater, and greater than about 98% at a wavelength of about 400 nm or greater.

The photoimprinted materials and films described herein are suitable for use within electronic devices. Electronic devices may include any devices that utilize electrical mechanisms, mechanical chemical mechanisms or combinations thereof to provide a function to a device. For example metal layers may be utilized to provide electrical connectivity or microprocessing. The film features 401 described herein can be used to form circuitry to provide the desired function to the electronic device. By “circuitry” it is meant that conductive, non-conductive cavities, wells, hollow spaces or pathways formed with the low dielectric film, are intermediate or adjacent to film features 401, and have functionality that is desirable for electronic devices. For example, circuitry may include integrated circuits formed from metal layer interconnects to provide microprocessing functionality. Also, for example, sensors may utilize pathways or chemical interactions within the hollow areas formed by film features 401 to provide chemical or gaseous sensing capabilities. The film can also provide advantageous dielectric constant stability, cracking resistance, and/or adhesion to the underlying substrate and/or other films. Suitable applications for the patterned film comprise interlayer insulating films for semiconductor devices such as LSIs, system LSIs, DRAMs, SDRAMs, RDRAMs, and D-RDRAMs, protective films such as surface coat films for semiconductor devices, insulating films for multilayered printed circuit boards, protective or insulating films for liquid-crystal display devices, OLEDs, electrophoretic devices, or other displays, gate dielectrics for thin film transistors, or an insulating film for thin film transistors in display, imaging, among other electronic devices.

Further non-limiting applications comprise photonics, nano-scale mechanical or nano-scale electrical devices, gas separations, liquid separations, or chemical sensors. Still further applications for the materials and films described herein can comprise at least one of flat panel displays, flexible displays, photovoltaics, solar cells, integrated circuits, memory manufacturing, RFID tags, sensors, smart objects, batteries, X-ray imaging or other imaging devices, among other devices. In the area of displays, liquid crystal displays (LCDs), organic light emitting diodes (OLEDs) or polymeric light emitting diodes (PLEDs), or electrophoretic devices may be driven by backplanes containing thin film transistor (TFT) arrays that may comprise the materials and films described herein. These displays may be described as active matrix liquid crystal displays (AMLCDs), active matrix organic light emitting devices (AMOLEDs), or active matrix polymer light emitting devices (AM-PLEDs), respectively. Electrophoretic displays may also be driven by such backplanes.

### EXAMPLES

### Example 1

### Low-Solvent Photodefinable Film Containing PAG

In Example 1, a film-forming composition was prepared containing the following: 18.0 grams of MTES as the silica source, 2.0 g of ethanol, 4.4 grams of the PAG (Bis(4-tert-butylphenyl)iodonium) triflate, and 6 grams of water. The composition was aged for 3 days and then the composition was partially polymerized by heating the composition to a temperature of 50° C. under vacuum to remove excess water and ethanol present from silicate hydrolysis. The viscosity of the aged and partially polymerized material was measured. The viscosity of the aged material was an average of 69cP when measured using a Brookfield viscometer at 25° C. at 100 rpm and torque of 2.8%. The resultant composition is suitable, for example, for spin casting onto substrate or ink jet printing onto substrates.

### Example 2

### Low-Solvent Photodefinable Film Containing PAG

In Example 2, a film-forming composition was prepared containing the following: 18.0 grams of MTES as the silica source, 2.7 g of ethanol, 4.4 grams of the PAG (Bis(4-tert-butylphenyl)iodonium) triflate, and 6 grams of water. The composition was aged for 6 days. Thereafter, the composition was partially polymerized by heating the composition to a temperature of 50° C. under vacuum to remove excess water and ethanol present from silicate hydrolysis. The viscosity of the aged and partially polymerized material was an average of 69 cP when tested at the same conditions as in Example 1. This solution was diluted with propylene glycol propyl ether (PGPE) and the solution spun onto a low resistivity silicon substrate, wherein the material was exposed to broad band UV radiation for 10 sec. The broad band ultraviolet light source referred to herein is manufactured by Fusion Systems using a “D” bulb, for 5 second. The films were baked at 90° C. for 90 seconds. A second bake was performed at 180° C. for 90 seconds. A third bake was performed at 250° C. for 90 seconds. A final bake was then performed at 400° C. for 3 minutes. In the first example, sufficient PGPE was added to the mixture to yield a 1.66 μm film. In a second example, the formulation was diluted further with PGPE to yield a 0.50 μm film. The resultant films had dielectric constant (k) values of 2.34 and 2.41, respectively.

### Comparative Example 1

### Nonphotoprintable Organosilicate Film Prepared without PAG

The following reagents were mixed together in a glass bottle and allowed to age either at room temperature for 7 days (Comp. Ex. 1a) or at 60° C. for 2 hours (Comp. Ex. 1b): 2.25 g of a 50/50 weight % mixture of TEOS/MTES, 4.77 g of PGPE, and 1.2 g of deionized water. Comp. Ex. 1a led to a heterogeneous solution while Comp. Ex 1b led to a homogeneous solution. Each composition was deposited onto a separate silicon wafer by dispensing 1 ml of the composition through a 0.2 micron Teflon filter onto the wafer. Each wafer was then spun for 7 seconds at 500 rpm then ramped to 1800 rpm for 40 seconds. The material resulting from Comp. Ex. 1a was unsuitable for photoimprinting, as the material present on the surface was minimal and was easily rinsed away with water. With the material of Comp. Ex. 1b, a film was formed.

The exemplary film from Comp. Ex. 1b is contacted with a quartz mold with mold features having spacings corresponding to film features having dimensions of about 100 nanometers (nm). The material is permitted to infiltrate the spacings of the mold. The material is then exposed to broad band UV radiation for 10 sec. Thereafter, the mold is removed from the film. The film lacked film feature definition and is easily removed by water.

### Example 3

### Low-Solvent Photodefinable Film Containing PAG and Porogen

In Example 3, a film-forming composition was prepared containing the following: 18.0 grams of MTES as the silica source, 2.0 grams of ethanol, 0.42 grams of the PAG (Bis(4-tert-butylphenyl)iodonium) triflate, 4.0 grams of Triton X-114 and 6 grams of water. The composition was aged 6 days. Thereafter, the composition was partially polymerized to remove excess water and ethanol present from silicate hydrolysis. Using a Model DVII Brookfield viscometer at 25° C. and a # 34 spindle, a viscosity of 76-90 cP was measured at 50 rpm using a torque of 0.7%. This solution was diluted with PGPE and the solution spun onto a low resistivity silicon substrate, wherein the material was exposed to broad band UV radiation using the source described above in Example 2 for 10 seconds. The films were baked at 90° C. for 90 seconds, with a second bake performed at 180° C. for 90 seconds and a third bake was performed at 250° C. for 90 seconds. A final bake was then performed at 400° C. for 3 minutes. In one film application, this formulation was diluted with sufficient PGPE to yield a 1.0 μm film. In another film, this formulation was diluted with sufficient PGPE to yield a 0.27 μm film. The resultant films had dielectric constant values of 2.68 and 2.74, respectively.

### Example 4

### Spun-On Photoimprintable Film Containing PAG and Porogen

In Example 4, a film-forming composition is prepared containing the following: 18.0 grams of MTES as the silica source, 2.7 g of ethanol, 4.4 grams of the PAG (Bis(4-tert-butylphenyl)iodonium) triflate, and 6 grams of water. The composition is aged for 6 days. Thereafter, the composition is partially polymerized by heating the composition to a temperature of 50° C. under vacuum to remove excess water and ethanol. This solution is diluted with the solvent propylene glycol propyl ether (PGPE) and the solution is spun onto a low resistivity silicon substrate. This exemplary film is contacted with a quartz mold with mold features having spacings corresponding to film features having dimensions of about 100 nanometers. The material is permitted to infiltrate the spacings of the mold. The material is then exposed to broad band UV radiation for 10 sec. Thereafter, the mold is removed from the film. The resultant photoimprinted film includes film features having dimensions of about 100 nm and are not rinsed away with a deionized water. Thereafter, the film from Ex. 4 is then baked on hot plates at 400° C. for 3 minutes.

### Example 5

### Ink Jet Printed Photoimprintable Film Containing PAG and Porogen

In Example 5, the film-forming composition of Example 4 is prepared and the composition is aged for 6 days. Thereafter, the composition is partially polymerized by heating the composition to a temperature of 50° C. under vacuum to remove excess water and ethanol. The film is selectively deposited onto the surface by an ink jet printer in a pattern corresponding to the spacings and film features corresponding to the photoimprinting mold. The exemplary film from Ex. 4 is contacted with a quartz mold with mold features having spacings corresponding to film features having dimensions of about 100 nanometers. The material is permitted to infiltrate the spacings of the mold. The material is then exposed to broad band UV radiation for 10 seconds. Thereafter, the mold is removed from the film. The resultant photoimprinted film includes film features having dimensions of about 100 nm that are not rinsed away with deionized water. The film formed in Ex. 5 is then baked on hot plates at 400° C. for 3 minutes to further cure film and/or reduce the dielectric constant of the film.

While the invention has been described with reference to a preferred embodiment, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

1. A process for preparing a photoimprinted film comprising a dielectric constant of less than about 3.5 on at least a portion of a substrate, the process comprising:
providing a material film onto the substrate, the material film having a composition comprising:
at least one silica source capable of being sol-gel processed;
at least one photoactive compound;
and water, the composition containing less than about 0.1% by weight of an added acid;
providing a mold having mold features;
positioning the mold in sufficient contact with the material film to allow the material film to contact at least a portion of the mold features;
exposing the material film to conditions sufficient to polymerize the material film and to form a solidified material film; and
separating the mold from the solidified material film, the solidified material film having film features corresponding to the mold features.

2. The process of claim 1, further comprising partially polymerizing the silica source prior to providing the material film.

3. The process of claim 2, wherein the partially polymerizing includes aging the composition.

4. The process of claim 2, further comprising removing at least a portion of the solvent from the composition prior to providing the material film.

5. The process of claim 2, further comprising removing at least a portion of water from the composition prior to providing the material film.

6. The process of claim 1, further comprising removing at least a portion of the solvent and water from the composition prior to providing the material film.

7. The process of claim 5, wherein the removing includes heating the composition.

8. The process of claim 1, wherein the providing includes spinning on the material film.

9. The process of claim 1, wherein the providing includes ink jet printing the material film.

10. The process of claim 9, wherein the ink jet printing includes selectively depositing the material film onto the substrate.

11. The process of claim 1, wherein the providing includes non-contact induced spreading of the material film.

12. The process of claim 1, wherein the positioning of the mold includes directing the mold into the material film.

13. The process of claim 1, wherein the positioning of the mold is prior to providing the material film to the substrate.

14. The process of claim 1, wherein the positioning of the mold further includes drawing the composition into spaces between the mold features.

15. The process of claim 1, wherein the composition comprises less than about 10 wt % solvent.

16. The process of claim 1, further comprising further curing the material film after the separating step.

17. The process of claim 1, wherein the exposing includes exposing the material film to radiation including an energy source selected from electron beam, photon, ultraviolet light, visible light, X-ray, thermal, and combinations thereof.

18. The process of claim 1, wherein the exposing step includes exposing the material film to ultraviolet or visible light.

19. A photoimprintable composition capable of forming a solidified material film having a dielectric constant of less than about 3.5, the composition comprising:
at least one partially polymerized silica source capable of being sol-gel processed;
at least one photoactive compound; and
wherein the composition has a degree of condensation, a solvent concentration, surface tension and a viscosity sufficient to render the composition capable of forming a film that can be photoimprinted.

20. The composition of claim 18, further comprising at least one porogen.

21. The composition of claim 18, wherein the photoactive compound comprises at least one member selected from the group consisting of a photoacid generator, a photobase generator, a photosensitizer, and combinations thereof.

22. The composition of claim 18, wherein the photoactive compound comprises at least one photoacid generator.

23. The composition of claim 18, wherein the photoactive compound further comprises at least one photosensitizer.

24. The composition of claim 18, wherein the silica source comprises at least one compound selected from a group consisting of compounds represented by the following formulas:
a) RₐSi(OR¹)₄₋ₐ, wherein R independently represents a hydrogen atom, a fluorine atom, or a monovalent organic group; R¹ represents a monovalent organic group; and a is an integer of 1 or 2;
b) Si(OR²)₄, where R² represents a monovalent organic group;
c) R³_{b}(R⁴O)_{3-b}Si—R⁷—Si(OR⁵)_{3-c}R⁶_{c}, wherein R⁴ and R⁵ may be the same or different and each represents a monovalent organic group; R³ and R⁶ may be the same or different; b and c may be the same or different and each is a number of 0 to 3; R⁷ represents an oxygen atom, a phenylene group, a biphenyl, a naphthalene group, or a group represented by —(CH₂)ₙ—, wherein n is an integer of 1 to 6; and mixtures thereof.

25. An electronic device comprising:
a substrate;
a functional component having a material film disposed on at least a portion of a surface of the substrate, the film having photoimprinted features, and a dielectric constant of less than about 3.5; and
wherein the functional component comprises circuitry for use in the electronic device.

26. The electronic device of claim 24, wherein the photoimprinted features further comprising a conductive layer disposed therein.

27. The electronic device of claim 24, wherein the material film is a photoimprinted ink jet printed film that has been cured by exposure to radiation.

28. The electronic device of claim 24, wherein the material film is a spin on film that has been cured by exposure to radiation.

29. The electronic device of claim 24, wherein the electronic device is a device selected from the group consisting of flat panel displays, flexible displays, photovoltaics, solar cells, basic logic devices, integrated circuits, memory manufacturing, RFID tags, sensors, smart objects, and imaging devices.

30. The electronic device of claim 24, wherein the electronic device is a photovoltaic cell

31. The electronic device of claim 24, wherein the electronic device is an integrated circuit

32. The electronic device of claim 24, wherein the electronic device is an electronic display.

33. The electronic device of claim 24, wherein the circuitry includes metallized interconnects.

34. The electronic device of claim 24, wherein the circuitry includes hollow pathways, well or cavities.
